(19) United States
(12) Patent Application Publication
(10) Pub. No.: US 2026/0180507 A1
(43) Pub. Date: Jun. 25, 2026

(54) VOLTAGE-CONTROLLED OSCILLATOR STRUCTURE

(71) Applicant: NATIONAL CHUNG SHAN INSTITUTE OF SCIENCE AND TECHNOLOGY, Taoyuan City (TW)

(72) Inventor: HSUAN-LING KAO, Taoyuan City (TW)

(73) Assignee: NATIONAL CHUNG SHAN INSTITUTE OF SCIENCE AND TECHNOLOGY, Taoyuan City (TW)

(21) Appl. No.: 19/375,247

(22) Filed: Oct. 31, 2025

(30) Foreign Application Priority Data
Dec. 19, 2024 (TW) 113149646

(51) Int. Cl. H03B 5/12

(52) U.S. Cl. CPC H03B 5/1212; H03B 5/1228; H03B 2200/0014; H03B 2200/009

(57) ABSTRACT

The present disclosure provides a voltage-controlled oscillator structure for a communication circuit. The structure includes a cross-coupling circuit and a transmission line module. The cross-coupling circuit has a first transistor, a first capacitor, a second transistor, and a second capacitor. The transmission line module has a first transmission line unit and a second transmission line unit. A transmission line effect of the cross-coupling circuit is eliminated through the transmission line module, so as to reduce phase noise of a voltage-controlled oscillator, thereby further achieving a purpose of increasing a communication frequency range.

This non-provisional application claims priority under 35 U.S.C. § 119 (a) on Patent Application No(s). 113149646 filed in Taiwan, R.O.C. on Dec. 19, 2024, the entire contents of which are hereby incorporated by reference.

### BACKGROUND OF THE INVENTION

### 1. Field of the Invention

The present disclosure relates to a voltage-controlled oscillator structure, and in particular, to a voltage-controlled oscillator structure for a communication circuit.

### 2. Description of the Related Art

With the rapid development of a communication system, an increasing requirement is imposed on a communication circuit used in the communication system. To improve noise resistance of the communication circuit, a voltage-controlled oscillator is often used to enhance the noise resistance of the communication circuit.

A conventional Class-F voltage-controlled oscillator uses a coupling winding unit to increase an oscillation voltage of the communication circuit. An additional impedance peak value is obtained through a third harmonic effect, forming a quasi-square wave output voltage. FIG. 1 is a schematic diagram of a Class-F voltage-controlled oscillator according to Chinese Patent No. CN110677127. As shown in the figure, the structure includes a first oscillation cavity 11, a cross-coupling circuit 12, and a second oscillation cavity 13. The cross-coupling circuit 12 has a first transistor 121 and a second transistor 122. A gate of the first transistor 121 is electrically connected to a drain of the second transistor 122, and a drain of the first transistor 121 is electrically connected to a gate of the second transistor 122. The first oscillation cavity 11 has a first capacitor 111, a second capacitor 112, and an inductor 113. The first capacitor 111, the second capacitor 112, and the inductor 113 are connected in parallel, and the two ends thereof are electrically connected to the drains of the first transistor 121 and the second transistor 122. The two connected ends are respectively used as an output terminal A and an input terminal B of the voltage-controlled oscillator. A double impedance is generated through the first oscillation cavity 11. A triple impedance is generated through the second oscillation cavity 13. Through the impedance suppression design method, a Class-F effect is reduced, and a circuit area required by the design method also increases.

### BRIEF SUMMARY OF THE INVENTION

In view of the above shortcomings of the foregoing conventional technology, the present disclosure is mainly intended to provide a voltage-controlled oscillator structure for a communication circuit. The voltage-controlled oscillator structure includes a cross-coupling circuit and a transmission line module. The cross-coupling circuit has a first transistor, a first capacitor, a second transistor, and a second capacitor. One end of the first capacitor is electrically connected to the drain of the first transistor, and one end of the second capacitor is electrically connected to the drain of the second transistor. The transmission line module is electrically connected to the cross-coupling circuit. The transmission line module has a first transmission line unit and a second transmission line unit. One end of the first transmission line unit is electrically connected to another end of the second capacitor, and another end of the first transmission line unit is electrically connected to the gate of the first transistor. One end of the second transmission line unit is electrically connected to another end of the first capacitor, and another end of the second transmission line unit is electrically connected to the gate of the second transistor. A transmission line effect of the cross-coupling circuit is eliminated through the transmission line module, so as to reduce phase noise of a voltage-controlled oscillator, thereby further achieving a purpose of increasing a communication frequency range. The transmission line module further includes: a first resistor, where one end of the first resistor is electrically connected to the gate of the first transistor and the another end of the first transmission line unit; and a second resistor, where one end of the second resistor is electrically connected to the gate of the second transistor and the another end of the second transmission line unit.

The first transistor and the second transistor of the voltage-controlled oscillator structure of the present disclosure are field-effect transistors.

The transmission line module of the voltage-controlled oscillator structure of the present disclosure further includes a third capacitor. One end of the third capacitor is electrically connected to the one end of the first transmission line unit, and another end of the third capacitor is electrically connected to the one end of the second transmission line unit.

### BRIEF DESCRIPTION OF THE DRAWINGS

FIG. 1 is a schematic diagram of a Class-F voltage-controlled oscillator according to Chinese Patent No. CN110677127.

FIG. 2 is a schematic diagram of a first embodiment of a voltage-controlled oscillator structure according to the present disclosure.

FIG. 3 is a schematic diagram of a second embodiment of a voltage-controlled oscillator structure according to the present disclosure.

### DETAILED DESCRIPTION OF THE INVENTION

Implementations of the present disclosure are described below through specific examples. Any person skilled in the art can understand other advantages and effects of the present disclosure from the content disclosed in this specification.

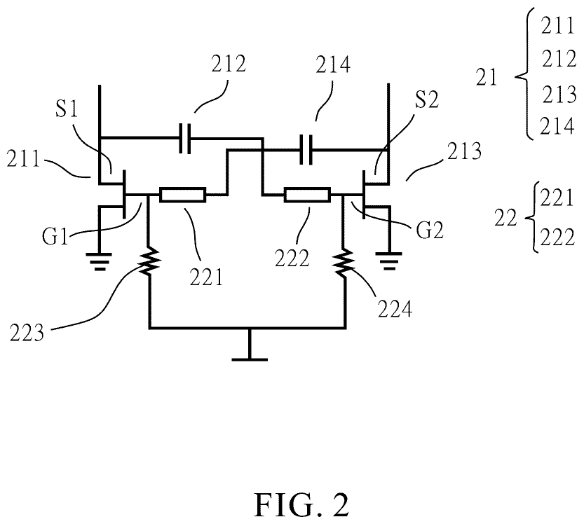

FIG. 2 is a schematic diagram of a first embodiment of a voltage-controlled oscillator structure according to the present disclosure. FIG. 2 shows a voltage-controlled oscillator structure for a communication circuit. The voltage-controlled oscillator structure includes a cross-coupling circuit 21 and a transmission line module 22. The cross-coupling circuit 21 has a first transistor 211, a first capacitor 212, a second transistor 213, and a second capacitor 214. One end of the first capacitor 212 is electrically connected to a drain S1 of the first transistor 211, and one end of the second capacitor 214 is electrically connected to a drain S2 of the second transistor 214. A source (not shown in the figure) of the first transistor 211 is electrically connected to a ground terminal. Another end of the first capacitor 212 is electrically connected to one end of a second transmission line unit 222. A source (not shown in the figure) of the second transistor 213 is electrically connected to the ground terminal. Another end of the second capacitor 214 is electrically connected to one end of a first transmission line unit 221. In addition, a gate G1 of the first transistor 211 and another end of the first transmission line unit 221 are electrically connected to one end of a first resistor 223. A gate G2 of the second transistor 213 and another end of the second transmission line unit 222 are electrically connected to one end of a second resistor 224. Another end of the first resistor 223 is electrically connected to another end of the second resistor 224.

The transmission line module 22 is electrically connected to the cross-coupling circuit 21. The transmission line module 22 has the first transmission line unit 221 and the second transmission line unit 222. The one end of the first transmission line unit 221 is electrically connected to another end of the second capacitor 214. Another end of the first transmission line unit 221 is electrically connected to the gate G1 of the first transistor 211. The one end of the second transmission line unit 222 is electrically connected to another end of the first capacitor 212. Another end of the second transmission line unit 222 is electrically connected to the gate G2 of the second transistor 213. A transmission line effect of the cross-coupling circuit 21 is eliminated through the transmission line module 22, so as to reduce phase noise of a voltage-controlled oscillator, thereby further achieving a purpose of increasing a communication frequency range. More specifically, the transmission line module 22 (equivalent to an inductor) and the first capacitor 212/the second capacitor 214 are caused to more likely to generate negative resistance at a low frequency. However, the negative resistance may eliminate positive resistance in the first oscillation cavity. Therefore, an oscillation condition is easily met, a size of the transistor is reduced, power consumption is lowered, and the phase noise is reduced, thereby further achieving the purpose of increasing the communication frequency range.

In addition, an inductance value of the transmission line module 22 and capacitance values of the first capacitor 212/the second capacitor 214 can adjust an appropriate negative resistance value to provide the oscillation condition. As shown in the following formula, L_{ML4} is an inductance of a transmission line, and Cgs is a parasitic resistance of the transistor.

$${G}_{N} = \frac{1}{1 - {ω}^{2} {L}_{ML 4} {C}_{gs}} ( - {g}_{m} )$$

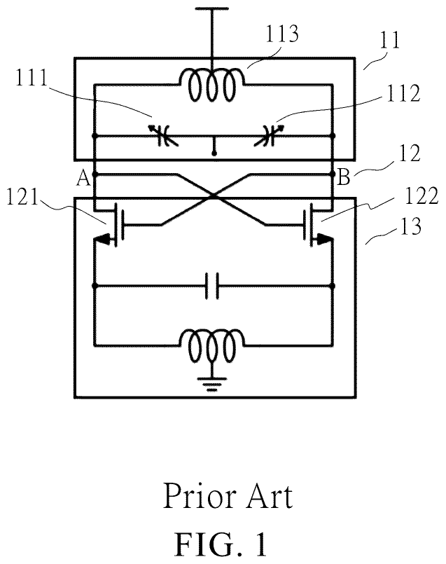

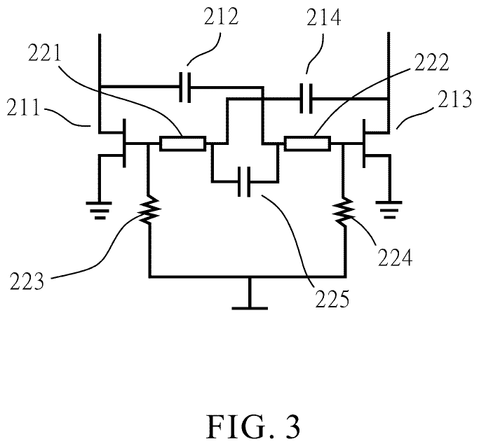

FIG. 3 is a schematic diagram of a second embodiment of a voltage-controlled oscillator structure according to the present disclosure. As shown in the figure, to enhance a triple frequency effect generated by the voltage-controlled oscillator, a gate G1 of a first transistor 211 and another end of the first transmission line unit 221 are electrically connected to one end of a first resistor 223. A gate G2 of a second transistor 213 and another end of a second transmission line unit 222 are electrically connected to one end of a second resistor 224, and another end of the first resistor 223 is electrically connected to another end of the second resistor 224. In addition, a third capacitor 225 is electrically connected between the one end of the first transmission line unit 221 and the one end of the second transmission line unit 222. More specifically, one end of the third capacitor 225 is electrically connected to the one end of the first transmission line unit 221, and another end of the third capacitor 225 is electrically connected to the one end of the second transmission line unit 222. Through the first resistor 223, the second resistor 224, and the third capacitor 225, impedance generated by the voltage-controlled oscillator can be enhanced, so that waveform outputted by the voltage-controlled oscillator approaches a square wave, thereby achieving a purpose of enhancing the voltage-controlled oscillator to eliminate phase noise of a communication circuit. More specifically, a third harmonic is generated through the third capacitor 225, the first transmission line unit 221/the second transmission line unit 222, and the first capacitor 212/the second capacitor 214. An additional impedance peak value is obtained at a triple frequency, so that waveform outputted by the voltage-controlled oscillator approaches a square wave, thereby achieving the purpose of enhancing the voltage-controlled oscillator to eliminate the phase noise of the communication circuit. In this way, the voltage-controlled oscillator structure of the present disclosure replaces the second oscillation cavity 13 in FIG. 1 with the third capacitor 225.

The foregoing embodiments are merely illustrative descriptions of the features and effects of the present disclosure, and are not intended to limit the scope of substantial technical content of the present disclosure. Any person skilled in the art may modify and vary the foregoing embodiments without departing from the spirit and scope of the present disclosure. Therefore, the protection scope of the claims of the present disclosure shall be subject to the scope of the claims described below.

While the present disclosure has been described by means of specific embodiments, numerous modifications and variations could be made thereto by those skilled in the art without departing from the scope and spirit of the present disclosure set forth in the claims.

What is claimed is:

1. A voltage-controlled oscillator structure for a communication circuit, the voltage-controlled oscillator structure comprising:
a cross-coupling circuit, having a first transistor, a first capacitor, a second transistor, and a second capacitor, wherein one end of the first capacitor is electrically connected to a drain of the first transistor, and one end of the second capacitor is electrically connected to a drain of the second transistor; and
a transmission line module, electrically connected to the cross-coupling circuit, wherein the transmission line module has a first transmission line unit and a second transmission line unit, one end of the first transmission line unit is electrically connected to another end of the second capacitor, another end of the first transmission line unit is electrically connected to a gate of the first transistor, one end of the second transmission line unit is electrically connected to another end of the first capacitor, another end of the second transmission line unit is electrically connected to a gate of the second transistor, and a transmission line effect of the cross-coupling circuit is eliminated through the transmission line module, so as to reduce phase noise of a voltage-controlled oscillator, wherein
the transmission line module further comprises:
a first resistor, wherein one end of the first resistor is electrically connected to the gate of the first transistor and the another end of the first transmission line unit; and
a second resistor, wherein one end of the second resistor is electrically connected to the gate of the second transistor and the another end of the second transmission line unit, and another end of the first resistor is electrically connected to another end of the second resistor.

2. The voltage-controlled oscillator structure according to claim 1, wherein the first transistor and the second transistor are field-effect transistors.

3. The voltage-controlled oscillator structure according to claim 1, wherein the transmission line module further comprises a third capacitor, one end of the third capacitor is electrically connected to the one end of the first transmission line unit, and another end of the third capacitor is electrically connected to the one end of the second transmission line unit.
